(19) United States
(12) Patent Application Publication
(10) Pub. No.: US 2015/0076707 A1
(43) Pub. Date: Mar. 19, 2015

(54) INTEGRATED CIRCUIT VIA STRUCTURE AND METHOD OF FABRICATION

(71) Applicants: STMicroelectronics, Inc., Coppell, TX (US); International Business Machines Corporation, Armonk, NY (US); Tokyo Electron Limited, Tokyo (JP)

(72) Inventors: Yann Mignot, Slingerlands, NY (US); Yannick Feurprier, Watervliet, NY (US); Wayne Meher, East Green Bush, NY (US)

(73) Assignees: STMicroelectronics, Inc., Coppell, TX (US); International Business Machines Corporation, Armonk, NY (US); Tokyo Electron Limited, Tokyo (JP)

(21) Appl. No.: 14/030,092

(22) Filed: Sep. 18, 2013

(51) Int. Cl. H01L 21/768; H01L 23/48

(52) U.S. Cl. CPC H01L 21/76802; H01L 23/481
USPC 257/774; 438/694

(57) ABSTRACT

A method for creating one or more vias in an integrated circuit structure and the integrated circuit structure. The method includes depositing a coating layer over a hard mask layer on the integrated circuit structure; locating an initial via pattern layer over the coating layer; and etching the pattern of the one or more initial openings in the coating layer and through openings in the hard mask layer. The coating layer is a conformal deposition of an oxide, a boron nitride, or other nitride. The initial via pattern layer has one or more initial openings located therein.

### TECHNICAL FIELD

The present disclosure relates to the fabrication of integrated circuits, and in particular, to the fabrication of vias.

### BACKGROUND

Modern electronic systems are often composed of integrated circuits (ICs) fabricated on small rectangular portions of flat wafers. The small rectangular portions of the wafers are commonly known as dies and as chips. Individual components of a given integrated circuit are formed by the addition of successive thin planer layers of various materials and the subsequent removal of portions of the added layers which results in the formation of patterned layers on the wafers. Selected areas of particular patterned layers are then coupled together conductively to form the components and the circuits.

An important part of this process is the creation of vias or openings between one or more upper layers and one or more lower layers to provide paths by which elements of the upper and lower layers can be conductively interconnected. Vias are formed between the upper and lower layers by the removal of selected areas of layers intermediate between the upper and lower layers.

There is a continuing trend toward manufacturing integrated circuits with higher component densities. This down-scaling of integrated circuit dimensions can facilitate faster circuit performance and/or switching speeds, and can lead to higher cost efficiency in IC fabrication by providing more circuits on a die and/or more die per semiconductor wafer. Smaller feature sizes of necessity mean smaller via sizes.

### BRIEF DESCRIPTION OF THE DRAWINGS

Example embodiments of the present disclosure will be described below with reference to the included drawings such that like reference numerals refer to like elements and in which:

FIG. 1A illustrates a first side view of an integrated circuit structure at a first via structure creation stage in accordance with embodiments of the present disclosure;

FIG. 1B illustrates a second side view of the integrated circuit structure of FIG. 1A at the first via structure creation stage in accordance with embodiments of the present disclosure;

FIG. 2A illustrates a first side view of the integrated circuit structure of FIG. 1A and FIG. 1B at a first optional via structure creation stage in accordance with embodiments of the present disclosure;

FIG. 2B illustrates a second side view of the integrated circuit structure of FIG. 1A and FIG. 1B at the first optional via structure creation stage in accordance with embodiments of the present disclosure;

FIG. 3A illustrates a first side view of the integrated circuit structure of FIG. 1A and FIG. 1B at a second via structure creation stage in accordance with embodiments of the present disclosure;

FIG. 3B illustrates a second side view of the integrated circuit structure of FIG. 1A and FIG. 1B at the second via structure creation stage in accordance with embodiments of the present disclosure;

FIG. 4A illustrates a first side view of the integrated circuit structure of FIG. 1A and FIG. 1B at a third via structure creation stage in accordance with embodiments of the present disclosure;

FIG. 4B illustrates a second side view of the integrated circuit structure of FIG. 1A and FIG. 1B at the third via structure creation stage in accordance with embodiments of the present disclosure;

FIG. 5A illustrates a first side view of the integrated circuit structure of FIG. 1A and FIG. 1B at a fourth via structure creation stage in accordance with embodiments of the present disclosure;

FIG. 5B illustrates a second side view of the integrated circuit structure of FIG. 1A and FIG. 1B at the fourth via structure creation stage in accordance with embodiments of the present disclosure;

FIG. 6A illustrates a first side view of the integrated circuit structure of FIG. 1A and FIG. 1B at a fifth via structure creation stage in accordance with embodiments of the present disclosure;

FIG. 6B illustrates a second side view of the integrated circuit structure of FIG. 1A and FIG. 1B at the fifth via structure creation stage in accordance with embodiments of the present disclosure;

FIG. 7A illustrates a first side view of the integrated circuit structure of FIG. 1A and FIG. 1B at a sixth via structure creation stage in accordance with embodiments of the present disclosure;

FIG. 7B illustrates a second side view of the integrated circuit structure of FIG. 1A and FIG. 1B at the sixth via structure creation stage in accordance with embodiments of the present disclosure;

FIG. 8A illustrates a first side view of the integrated circuit structure of FIG. 1A and FIG. 1B at another first via structure creation stage in accordance with embodiments of the present disclosure;

FIG. 8B illustrates a second side view of the integrated circuit structure of FIG. 1A and FIG. 1B at the yet another first via structure creation stage in accordance with embodiments of the present disclosure;

FIG. 9A illustrates a first side view of the integrated circuit structure of FIG. 1A and FIG. 1B at still another first via structure creation stage in accordance with embodiments of the present disclosure;

FIG. 9B illustrates a second side view of the integrated circuit structure of FIG. 1A and FIG. 1B at the still another first via structure creation stage in accordance with embodiments of the present disclosure;

FIG. 10 illustrates a flow chart of a method for creating a via structure in an integrated circuit structure in accordance with embodiments of the present disclosure; and

FIG. 11 illustrates a flow chart of another method for creating a via structure in an integrated circuit structure in accordance with embodiments of the present disclosure.

### DETAILED DESCRIPTION

For simplicity and clarity of illustration, reference numerals may be repeated among the figures to indicate corresponding or analogous elements. The sizes and relative positions of elements in the drawings are not necessarily drawn to scale. Numerous details are set forth to provide an understanding of the illustrative embodiments described herein. The embodiments may be practiced without these details. In other instances, well-known methods, procedures, and components have not been described in detail to avoid obscuring the disclosed embodiments. The description is not to be considered as limited to the scope of the exemplary embodiments shown and described herein.

The terms “a” or “an”, as used herein, are defined as one or more than one. The term “plurality”, as used herein, is defined as two or more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically. The term “or” as used herein is to be interpreted as an inclusive or meaning any one or any combination. Therefore, “A, B or C” means “any of the following: A; B; C; A and B; A and C; B and C; A, B and C”. An exception to this definition will occur only when a combination of elements, functions, steps or acts are in some way inherently mutually exclusive.

Reference throughout this document to “one embodiment”, “certain embodiments”, “an embodiment”, “an example”, “an implementation”, “an example” or similar terms means that a particular feature, structure, or characteristic described in connection with the embodiment, example or implementation is included in at least one embodiment, example or implementation of the present invention. Thus, the appearances of such phrases or in various places throughout this specification are not necessarily all referring to the same embodiment, example or implementation. Furthermore, the particular features, structures, or characteristics may be combined in any suitable manner in one or more embodiments, examples or implementations without limitation.

Unless the context requires otherwise, throughout the specification and claims that follow, the word “comprise” and variations thereof, such as “comprises” and “comprising” are to be construed in an open, inclusive sense, that is, as “including, but not limited to.”

As shown in the drawings for purposes of illustration, novel techniques are disclosed herein for integrated circuit via structures and methods for the fabrication of integrated circuit via structures. Via structure patterning schemes are disclosed which can be used in a single or a double via structure patterning process.

Previously an organic planarization layer (OPL) has been used as a via mask in preparation for final metal deposition in typical trench processes. As taught herein, a coating layer is inserted beneath the organic planarization layer. This coating layer is a hard layer the material of which could be, but is not limited to, an oxide. It is a sacrificial layer during via etch and subsequent trench etching and prevents dielectric damage during organic planarization layer strip removal. It also enables the use of a thinner titanium nitride (TiN) hard mask which needs to be eventually removed or faceted for non-void post-etch metal filling in via and trench locations. Also, the titanium nitride will experience less exposure to cumulative etching and can have less corner rounding and improvement in self-aligned critical dimension control. Via profile bowing may also be improved as a result of less dielectric damage generated during the organic planarization layer strip process.

The techniques disclosed can result in improved self aligned vias In addition, associated insulating layers have ultra low dielectric constants which can result in improvements in resistances and capacitances between various layers.

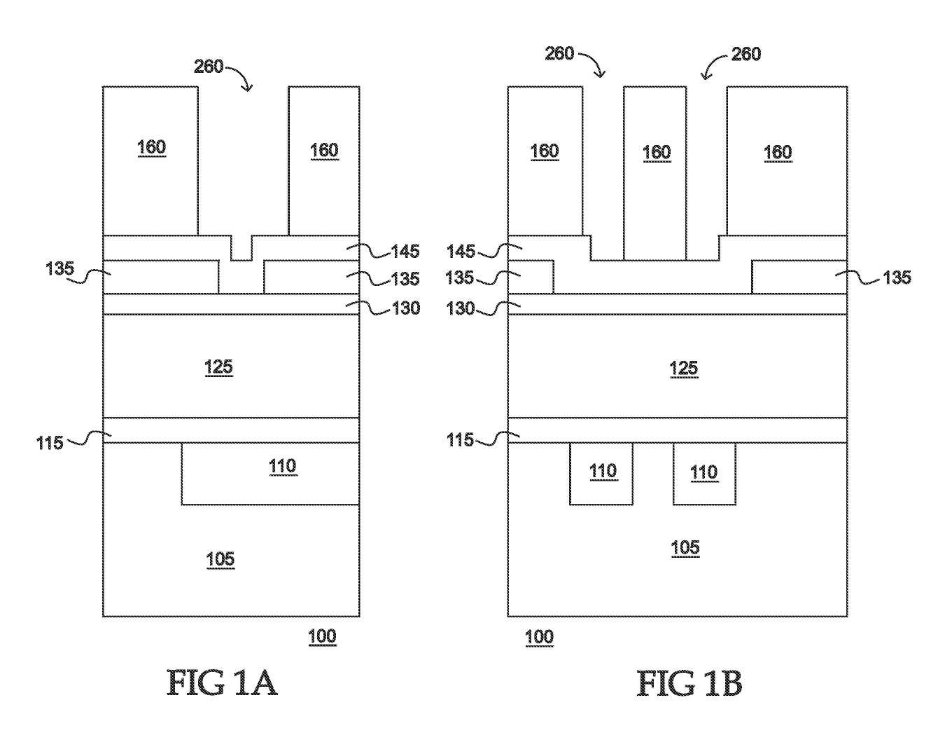

FIG. 1A illustrates a first side view of an integrated circuit structure 100 at a first via structure creation stage in accordance with embodiments of the present disclosure. In FIG. 1A, a conductive layer 110 overlays and is embedded in a base layer 105; a protective layer 115 overlays the base layer 105 and the conductive layer 110; a dielectric layer 125 overlays the protective layer 115; a sacrificial adhesive layer 130 overlays the dielectric layer 125; a hard mask layer 135 overlays the sacrificial adhesive layer 130; a coating layer 145 overlays the hard mask layer 135; and an initial via pattern layer 160 overlays the coating layer 145.

The material of the base layer 105 could be, but is not limited to, an oxide, an ultra low dielectric constant (ULK) oxide, or Tetraethyl orthosilicate (TEOS); the material of the conductive layer 110 could be, but is not limited to, copper; the material of the protective layer 115 could be, but is not limited to, a nitride, cyclique nitride or cobalt nitride; the material of the dielectric layer 125 could be, but is not limited to, an oxide, an ultra low dielectric constant (ULK) oxide, or Tetraethyl orthosilicate (TEOS); the material of the sacrificial adhesive layer 130 could be, but is not limited to, an oxide or Tetraethyl orthosilicate; the material of the hard mask layer 135 could be, but is not limited to, titanium nitride (TiN); and the material of the coating layer 145 could be, but is not limited to, a conformal deposition of an oxide, a nitride, or boron nitride such as, for example, a low temperature oxide (LTO) deposited by atomic-layer deposition (ADL) or a plasma-enhanced atomic layer deposition (PEALD) of silicon dioxide. The initial via pattern layer 160 can, in various optional implementations, comprise one or more sub-layers, the details of which will be discussed in connection with the appropriate subsequent figures.

The base layer 105 is used as a dielectric layer to avoid shorts between other conductive traces and the via; the conductive layer 110 is used to electrically interconnect various elements of the integrated circuit structure 100; the dielectric layer 125 is used to avoid shorts between the other conductive traces and the via; the sacrificial adhesive layer 130 provides adhesion between the dielectric layer 125 and the hard mask layer 135; and the coating layer 145 provides the required shrink for the via and aids to preserve the dielectric 125 from being exposed to a plasma source of damage.

FIG. 1B illustrates a second side view of the integrated circuit structure 100 of FIG. 1A at the first via structure creation stage in accordance with embodiments of the present disclosure.

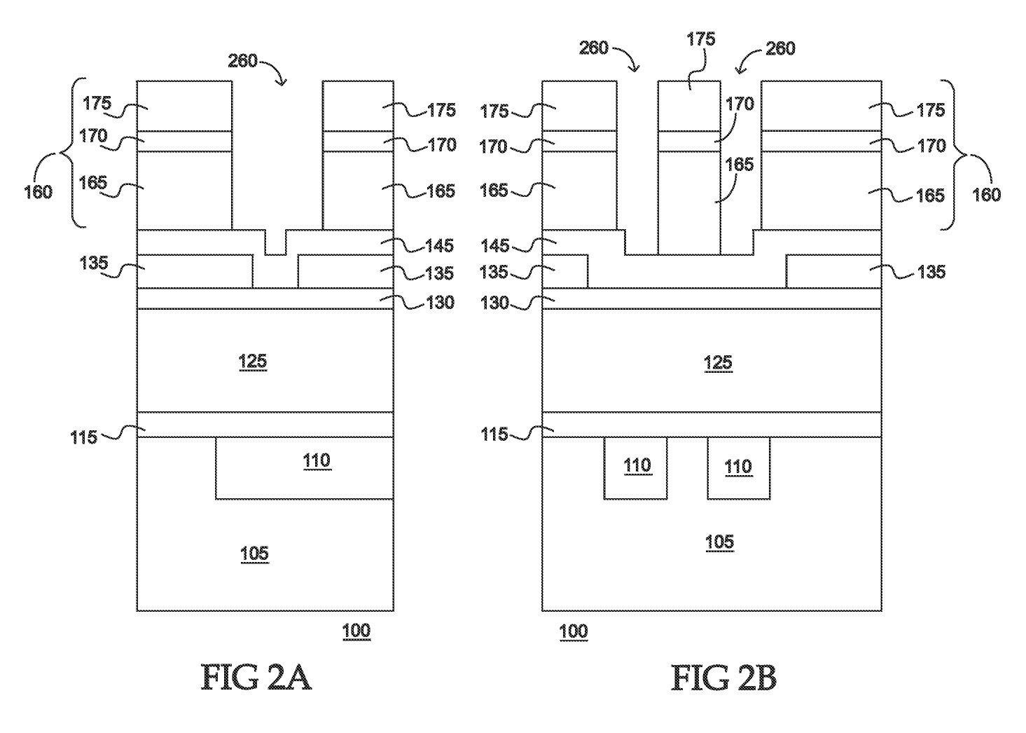

FIG. 2A illustrates a first side view of the integrated circuit structure 100 of FIG. 1A and FIG. 1B at a first optional via structure creation stage in accordance with embodiments of the present disclosure. In FIG. 2A, the initial via pattern layer 160 comprises a lower initial layer 165 overlaying the coating layer 145, an upper initial layer 170 overlaying the lower initial layer 165, and a photoresist layer 175 overlaying the upper initial layer 170. Prior to the view of FIG. 2A, the lower initial layer 165, the upper initial layer 170, and the photoresist layer 175 were deposited in order onto the wafer on which the integrated circuit structure 100 is being fabricated. Then the photoresist layer 175 is exposed and developed, and subsequently initial openings 260 are created by etching the three layers. The material of the upper initial layer 170 could be, but is not limited to, a Low Temperature Oxide (LTO). Alternatively, the upper initial layer 170 could be, but is not limited to, a Silicon Anti-Reflective Coating (SiARC) material. The material of the lower initial layer 165 could be, but is not limited to, an organic. The lower initial layer 165 is also referred to herein as an organic planarization layer (OPL) 165.

FIG. 2B illustrates a second side view of the integrated circuit structure 100 of FIG. 1A and FIG. 1B at the first optional via structure creation stage in accordance with embodiments of the present disclosure. Prior to the view of FIG. 2B, the integrated circuit structure 100 is processed as it was prior to the view of FIG. 2A.

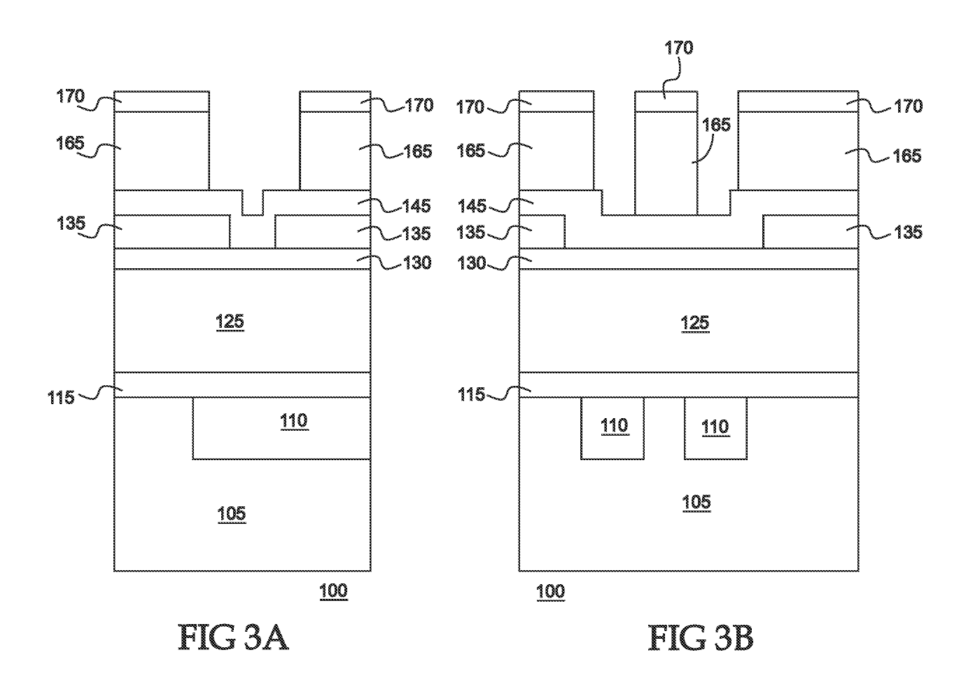

FIG. 3A illustrates a first side view of the integrated circuit structure 100 of FIG. 1A and FIG. 1B at a second via structure creation stage in accordance with embodiments of the present disclosure. Prior to the view of FIG. 3A, the photoresist layer 175 is stripped.

FIG. 3B illustrates a second side view of the integrated circuit structure 100 of FIG. 1A and FIG. 1B at the second via structure creation stage in accordance with embodiments of the present disclosure. Prior to the view of FIG. 3B, the integrated circuit structure 100 is processed as it was prior to the view of FIG. 3A.

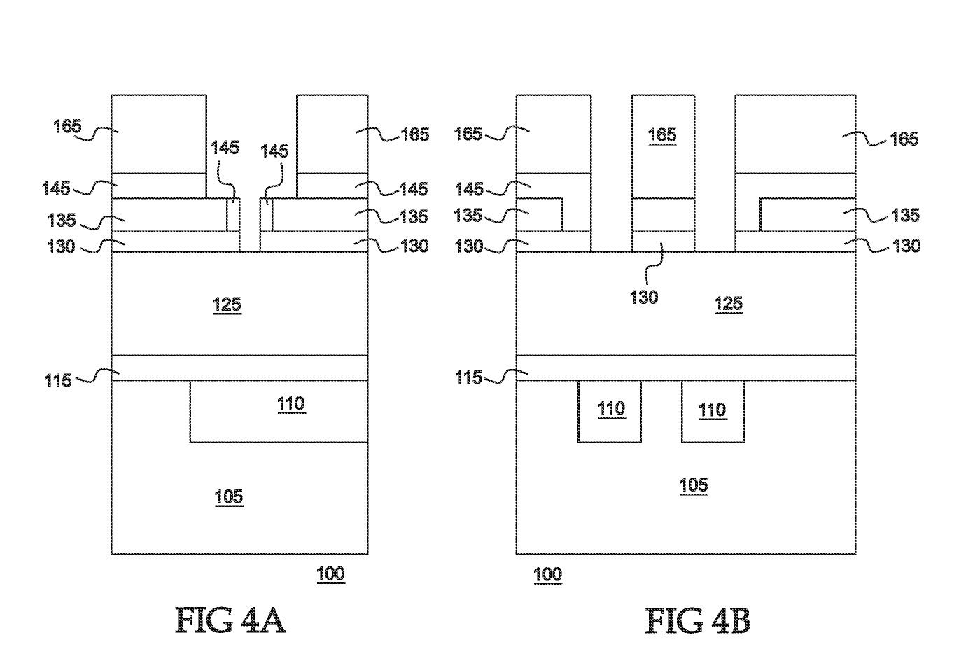

FIG. 4A illustrates a first side view of the integrated circuit structure 100 of FIG. 1A and FIG. 1B at a third via structure creation stage in accordance with embodiments of the present disclosure. Prior to the view of FIG. 4A, a reactive ion etch (RIE) is performed which removes the upper initial layer 170, preferentially in the vertical direction the exposed coating layer 145, and the exposed sacrificial adhesive layer 130 down to the dielectric layer 125.

FIG. 4B illustrates a second side view of the integrated circuit structure 100 of FIG. 1A and FIG. 1B at the third via structure creation stage in accordance with embodiments of the present disclosure. Prior to the view of FIG. 4B, the integrated circuit structure 100 is processed as it was prior to the view of FIG. 4A.

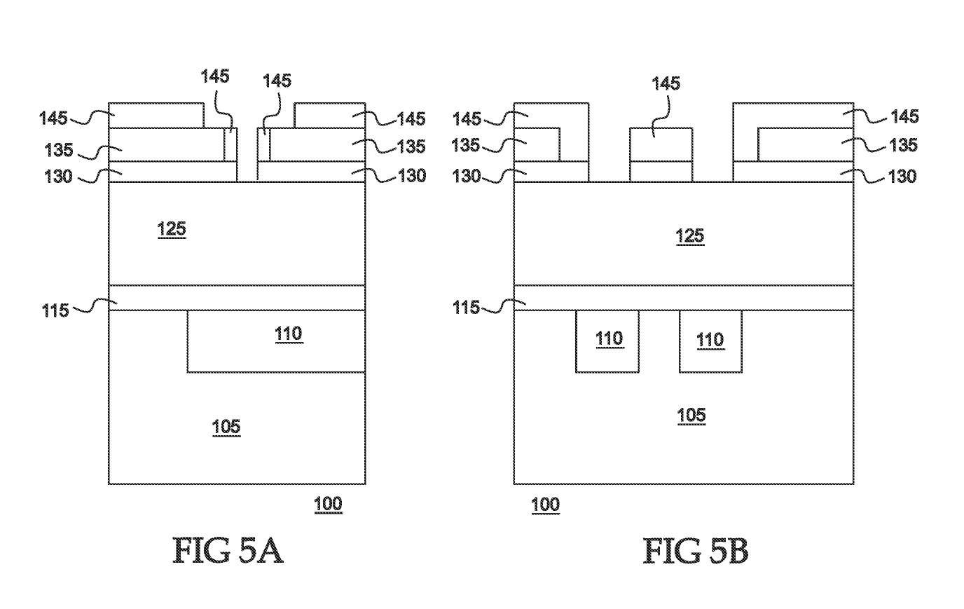

FIG. 5A illustrates a first side view of the integrated circuit structure 100 of FIG. 1A and FIG. 1B at a fourth via structure creation stage in accordance with embodiments of the present disclosure. Prior to the view of FIG. 5A, the lower initial layer 165 is stripped.

FIG. 5B illustrates a second side view of the integrated circuit structure 100 of FIG. 1A and FIG. 1B at the fourth via structure creation stage in accordance with embodiments of the present disclosure. Prior to the view of FIG. 5B, the integrated circuit structure 100 is processed as it was prior to the view of FIG. 5A.

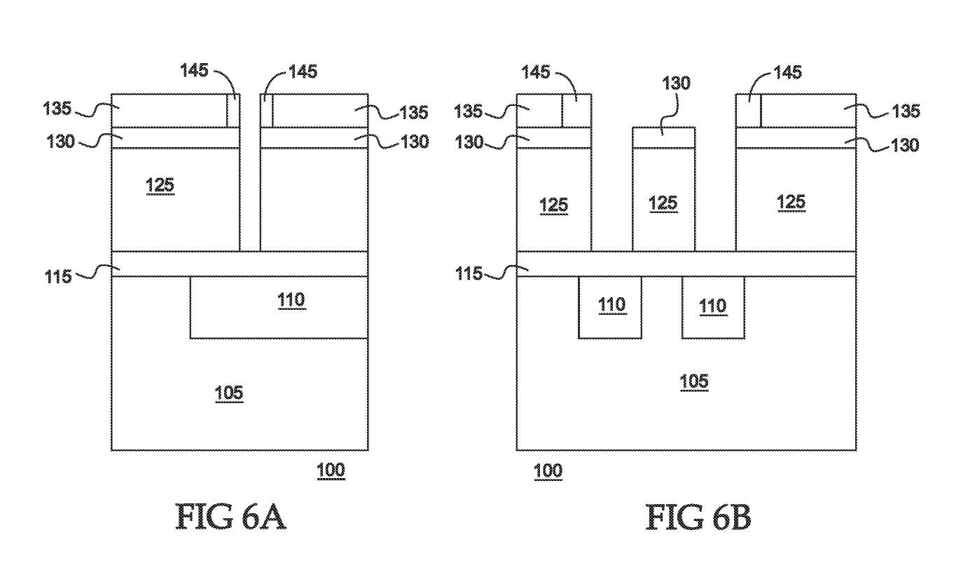

FIG. 6A illustrates a first side view of the integrated circuit structure 100 of FIG. 1A and FIG. 1B at a fifth via structure creation stage in accordance with embodiments of the present disclosure. Prior to the view of FIG. 6A, a reactive ion etch (RIE) is performed which removes preferentially in the vertical direction the exposed coating layer 145 and removes the exposed dielectric layer 125 down to the protective layer 115.

FIG. 6B illustrates a second side view of the integrated circuit structure 100 of FIG. 1A and FIG. 1B at the fifth via structure creation stage in accordance with embodiments of the present disclosure. Prior to the view of FIG. 6B, the integrated circuit structure 100 is processed as it was prior to the view of FIG. 6A.

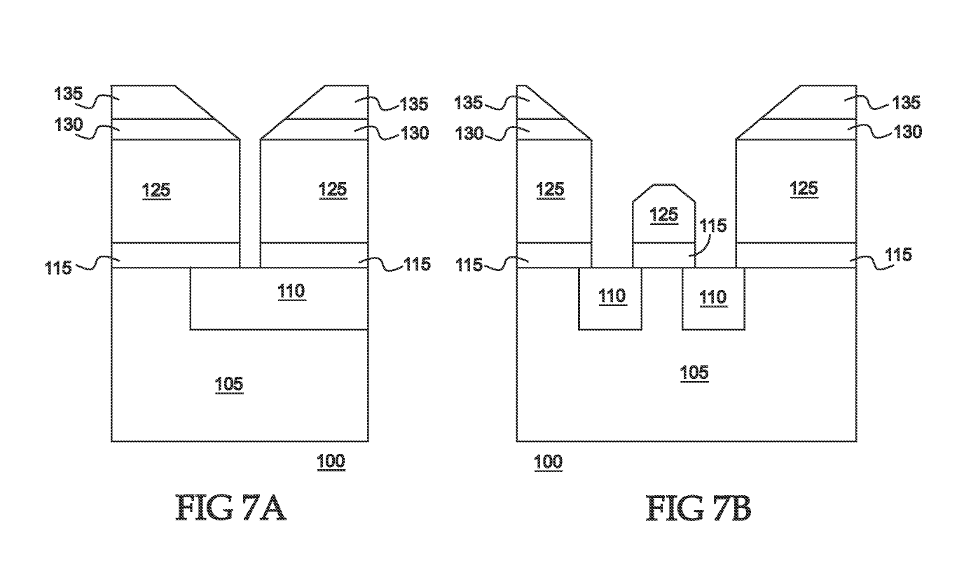

FIG. 7A illustrates a first side view of the integrated circuit structure 100 of FIG. 1A and FIG. 1B at a sixth via structure creation stage in accordance with embodiments of the present disclosure. Prior to the view of FIG. 7A, the integrated circuit structure 100 was trench etched using the hard mask layer 135 and the sacrificial adhesive layer 130 as masks.

FIG. 7B illustrates a second side view of the integrated circuit structure 100 of FIG. 1A and FIG. 1B at the sixth via structure creation stage in accordance with embodiments of the present disclosure. Prior to the view of FIG. 7B, the integrated circuit structure 100 is processed as it was prior to the view of FIG. 7A.

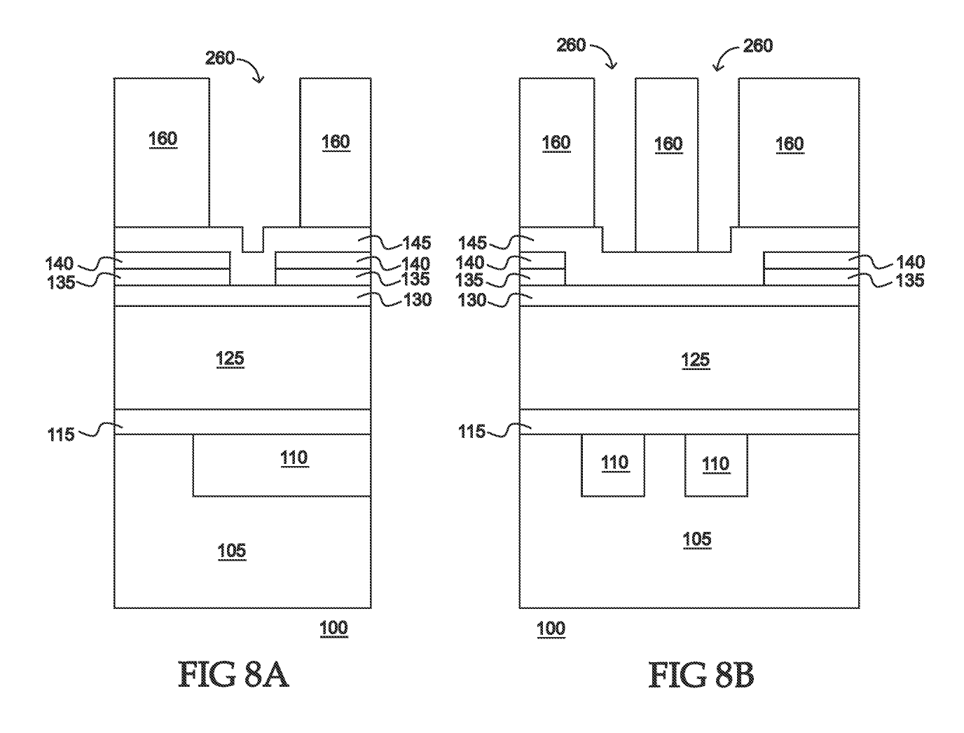

FIG. 8A illustrates a first side view of the integrated circuit structure 100 of FIG. 1A and FIG. 1B at another first via structure creation stage in accordance with embodiments of the present disclosure. The integrated circuit structure 100 in FIG. 8A is similar to that of FIG. 1A except that an oxide hard mask layer 140 has been added that overlays the hard mask layer 135 and the coating layer 145 overlays the oxide hard mask layer 140. The material of the oxide hard mask layer 140 could be, but is not limited to, Tetraethyl orthosilicate (TEOS) or a low temperature oxide (LTO).

FIG. 8B illustrates a second side view of the integrated circuit structure 100 of FIG. 1A and FIG. 1B at the yet another first via structure creation stage in accordance with embodiments of the present disclosure. Prior to the view of FIG. 8B, the integrated circuit structure 100 is processed as it was prior to the view of FIG. 8A.

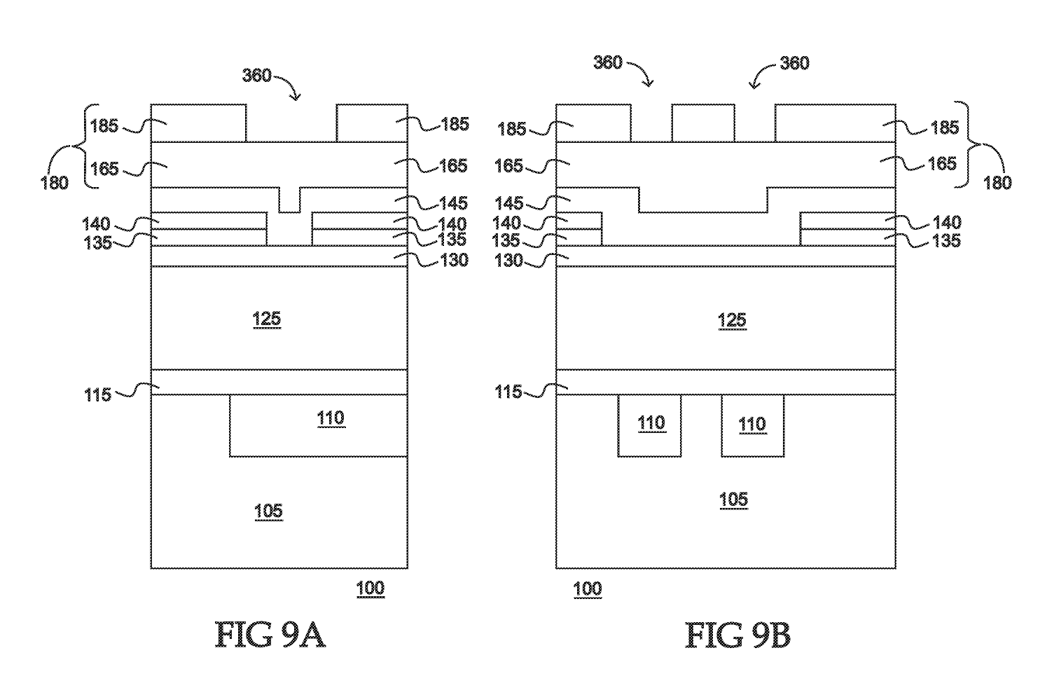

FIG. 9A illustrates a first side view of the integrated circuit structure 100 of FIG. 1A and FIG. 1B at still another first via structure creation stage in accordance with embodiments of the present disclosure. The integrated circuit structure 100 in FIG. 9A is similar to that of FIG. 1A except that an oxide hard mask layer 140 has been added that overlays the hard mask layer 135 and the coating layer 145 overlays the oxide hard mask layer 140. In FIG. 9, an initial via pattern layer 180 comprises a top layer 185 having one or more multi-patterned via openings 360 etched into it. The multi-patterned via openings 360 are created by memorizing two or more via lithographic mask steps into the top layer 185 which overlays a lower initial layer 165, the material of which could be, but is not limited to, an organic used for planarization. The top layer 185 could be, but is not limited to, an oxide or nitride layer from different deposition processes performed at Low temperatures in order to accommodate thermal stress and adhesion with the lower initial layer 165, i.e., the organic planarization layer 165. Prior to the view of FIG. 9A, one or more multi-patterned via openings 360 are etched into the top layer 185.

FIG. 9B illustrates a second side view of the integrated circuit structure 100 of FIG. 1A and FIG. 1B at the still another first via structure creation stage in accordance with embodiments of the present disclosure. Prior to the view of FIG. 9B, the integrated circuit structure 100 is processed as it was prior to the view of FIG. 9A.

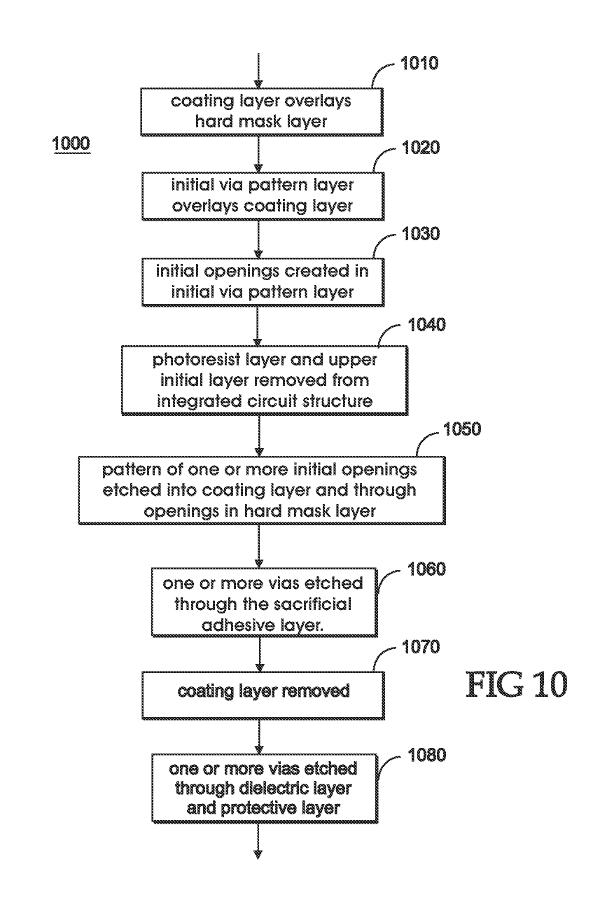

FIG. 10 illustrates a flow chart of a method 1000 for creating a via structure in an integrated circuit structure 100 in accordance with embodiments of the present disclosure. In block 1010 of FIG. 10, an integrated circuit structure 100 comprising a conductive layer 110 overlaying and embedded in a base layer 105, a protective layer 115 overlaying the conductive layer 110 and the base layer 105, a dielectric layer 125 overlying the protective layer 115, a sacrificial adhesive layer 130 overlaying the dielectric layer 125, and a hard mask layer 135 overlaying the sacrificial adhesive layer 130. In block 1010, a coating layer 145 overlays the hard mask layer 135. Processing techniques and materials for representative implementations are disclosed above. Block 1010 then transfers control to block 1020.

In block 1020, an initial via pattern layer 160 overlays the coating layer 145. The initial via pattern layer 160 comprises a lower initial layer 165, an upper initial layer 170, and a photoresist layer 175. Processing techniques and materials for representative implementations are disclosed above. Block 1020 then transfers control to block 1030.

In block 1030, one or more initial openings 260 are created in the initial via pattern layer 160. Processing techniques and materials for representative implementations are disclosed above. Block 1030 then transfers control to block 1040.

In block 1040, the photoresist layer 175 and the upper initial layer 170 are removed from the integrated circuit structure 100. Processing techniques and materials for representative implementations are disclosed above. Processing techniques and materials for representative implementations are disclosed above. Block 1040 then transfers control to block 1050.

In block 1050, the pattern of the one or more initial openings 260 is etched into the coating layer 145 and through openings in the hard mask layer 135. Processing techniques and materials for representative implementations are disclosed above. Processing techniques and materials for representative implementations are disclosed above. Block 1050 then transfers control to block 1060.

In block 1060, the one or more vias are etched through the sacrificial adhesive layer 130. Processing techniques and materials for representative implementations are disclosed above. Processing techniques and materials for representative implementations are disclosed above. Block 1060 then transfers control to block 1070.

In block 1070, the coating layer 145 is removed. Processing techniques and materials for representative implementations are disclosed above. Processing techniques and materials for representative implementations are disclosed above. Block 1070 then transfers control to block 1080.

In block 1080, the one or more vias are etched through the dielectric layer 125 and through the protective layer 115. Processing techniques and materials for representative implementations are disclosed above. Processing techniques and materials for representative implementations are disclosed above. Block 1080 then terminates the process.

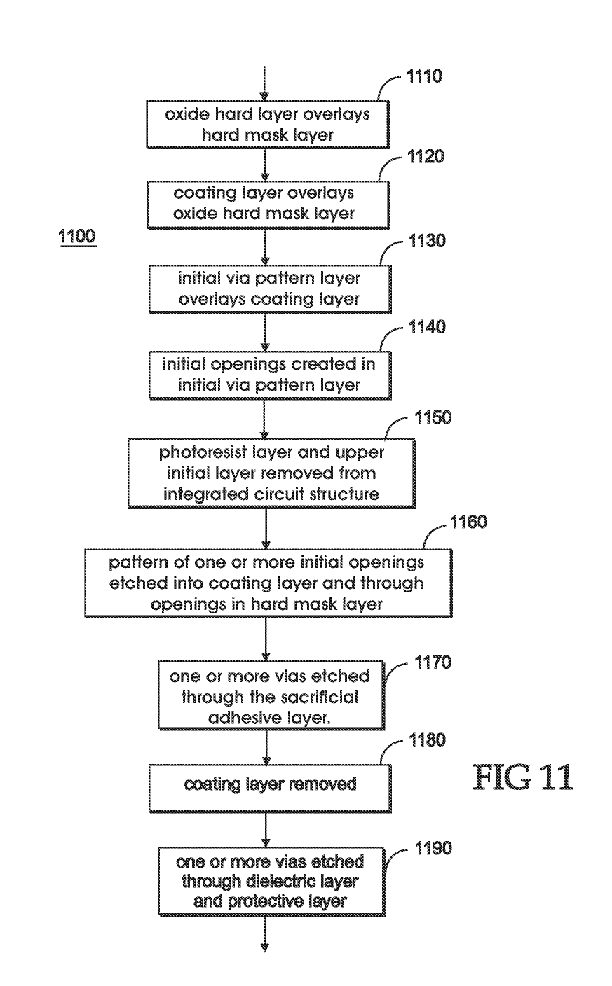

FIG. 11 illustrates a flow chart of another method 1100 for creating a via structure in an integrated circuit structure 100 in accordance with embodiments of the present disclosure. In block 1110 of FIG. 11, an integrated circuit structure 100 comprising a conductive layer 110 overlaying and embedded in a base layer 105, a protective layer 115 overlaying the conductive layer 110 and the base layer 105, a dielectric layer 125 overlying the protective layer 115, a sacrificial adhesive layer 130 overlaying the dielectric layer 125, and a hard mask layer 135 overlaying the sacrificial adhesive layer 130. In block 1110, the oxide hard mask layer 140 overlays the hard mask layer 135. Processing techniques and materials for representative implementations are disclosed above. Block 1110 then transfers control to block 1120.

In block 1120, a coating layer 145 overlays the oxide hard mask layer 140. Processing techniques and materials for representative implementations are disclosed above. Block 1120 then transfers control to block 1130.

In block 1130, an initial via pattern layer 160 overlays the coating layer 145. The initial via pattern layer 160 comprises a lower initial layer 165, an upper initial layer 170, and a photoresist layer 175. Processing techniques and materials for representative implementations are disclosed above. Block 1130 then transfers control to block 1140.

In block 1140, one or more initial openings 260 are created in the initial via pattern layer 160. The initial via pattern layer 160 could in this step comprise a top layer 185 having one or more multi-patterned via openings 360 etched into it or could be single patterned. Processing techniques and materials for representative implementations are disclosed above. Block 1140 then transfers control to block 1150.

In block 1150, the photoresist layer 175 and the upper initial layer 170 are removed from the integrated circuit structure 100. Processing techniques and materials for representative implementations are disclosed above. Processing techniques and materials for representative implementations are disclosed above. Block 1150 then transfers control to block 1160.

In block 1160, the pattern of the one or more initial openings 260 is etched into the coating layer 145 and through openings in the hard mask layer 135. Processing techniques and materials for representative implementations are disclosed above. Processing techniques and materials for representative implementations are disclosed above. Block 1160 then transfers control to block 1170.

In block 1170, the one or more vias are etched through the sacrificial adhesive layer 130. Processing techniques and materials for representative implementations are disclosed above. Processing techniques and materials for representative implementations are disclosed above. Block 1170 then transfers control to block 1180.

In block 1180, the coating layer 145 is removed. Processing techniques and materials for representative implementations are disclosed above. Processing techniques and materials for representative implementations are disclosed above. Block 1180 then transfers control to block 1190.

In block 1190, the one or more vias are etched through the dielectric layer 125 and through the protective layer 115. Processing techniques and materials for representative implementations are disclosed above. Processing techniques and materials for representative implementations are disclosed above. Block 1190 then terminates the process.

In a representative embodiment, a method 1000 for creating one or more vias in an integrated circuit structure 100 is disclosed. The method 1000 comprises depositing a coating layer 145 over a hard mask layer 135 on the integrated circuit structure 100; locating an initial via pattern layer 160 over the coating layer 145; and etching the pattern of the one or more initial openings 260 in the coating layer 145 and through openings in the hard mask layer 135. The coating layer 145 is a conformal deposition of an oxide, a boron nitride, or other nitride. The initial via pattern layer 160 has one or more initial openings 260 located therein.

In another representative embodiment, another method 1100 for creating one or more vias in an integrated circuit structure 100 is disclosed. The method 1100 comprises depositing an oxide hard mask layer 140 over a hard mask layer 135 on the integrated circuit structure 100; depositing a coating layer 145 over the oxide hard mask layer 140 on the integrated circuit structure 100; locating an initial via pattern layer 160 over the coating layer 145; and etching the pattern of the initial openings 260 in the coating layer 145 extending through openings in the oxide hard mask layer 140 and through openings in the hard mask layer 135. The coating layer 145 is a conformal deposition of an oxide, a boron nitride, or other nitride. The initial via pattern layer 160 has one or more initial openings 260.

In still another representative embodiment, an integrated circuit structure 100 is disclosed. The integrated circuit structure 100 comprises a coating layer 145 located over a hard mask layer 135 on the integrated circuit structure 100; and an initial via pattern layer 160 located over the coating layer 145. The coating layer 145 is a conformal deposition of an oxide, a boron nitride, or other nitride. An initial via pattern layer 160 has one or more initial openings 260 located therein, and the pattern of the one or more initial openings 260 was etched into the coating layer 145 and through openings in the hard mask layer.

The embodiments of the present disclosure described above are intended to be merely exemplary. It will be appreciated by those of skill in the art that alterations, modifications and variations to the illustrative embodiments disclosed herein may be made without departing from the scope of the present disclosure. Moreover, selected features from one or more of the above-described exemplary embodiments may be combined to create alternative embodiments not explicitly shown and described herein.

The present disclosure may be embodied in other specific forms without departing from its spirit or essential characteristics. The described exemplary embodiments are to be considered in all respects only as illustrative and not restrictive. The scope of the disclosure is, therefore, indicated by the appended claims rather than by the foregoing description. All changes that come within the meaning and range of equivalency of the claims are to be embraced within their scope.

What is claimed is:

1. A method for creating one or more vias in an integrated circuit structure, comprising:
depositing a coating layer over a hard mask layer on the integrated circuit structure,
wherein the coating layer is a conformal deposition of an oxide, a boron nitride, or other nitride;
locating an initial via pattern layer over the coating layer
wherein the initial via pattern layer has one or more initial openings located therein; and
etching the pattern of the one or more initial openings in the coating layer and through openings in the hard mask layer.

2. The method as recited in claim 1, wherein the hard mask layer comprises titanium nitride.

3. The method as recited in claim 1, wherein the initial via pattern layer comprises:
a lower initial layer located over the coating layer and comprising an organic material; and
an upper initial layer located over the lower initial layer and comprising a Low Temperature Oxide (LTO) or a Silicon Anti-Reflective Coating (SiARC) material.

4. The method as recited in claim 1, wherein the integrated circuit structure further comprises:
a conductive layer overlaying and embedded in a base layer;
a protective layer overlaying the conductive layer and the base layer;
a dielectric layer overlaying the protective layer; and
a sacrificial adhesive layer overlaying the dielectric layer,
wherein the hard mask layer overlays the sacrificial adhesive layer.

5. The method as recited in claim 1, wherein the protective layer comprises a nitride, cyclique nitride or cobalt nitride material.

6. The method as recited in claim 1, wherein the sacrificial adhesive layer comprises an oxide or Tetraethyl orthosilicate material.

7. The method as recited in claim 1, wherein the dielectric layer comprises an oxide, an ultra low dielectric constant oxide, or Tetraethyl orthosilicate material.

8. A method for creating one or more vias in an integrated circuit structure, comprising:
depositing an oxide hard mask layer over a hard mask layer on the integrated circuit structure;
depositing a coating layer over the oxide hard mask layer on the integrated circuit structure;
wherein the coating layer is a conformal deposition of an oxide, a boron nitride, or other nitride; and
locating an initial via pattern layer over the coating layer,
wherein the initial via pattern layer has one or more initial openings; and
etching the pattern of the initial openings in the coating layer extending through openings in the oxide hard mask layer and through openings in the hard mask layer.

9. The method as recited in claim 8, wherein the hard mask layer comprises titanium nitride.

10. The method as recited in claim 8, wherein the material of the oxide hard mask layer comprises Tetraethyl orthosilicate or a low temperature oxide.

11. The method as recited in claim 8, wherein the initial via pattern layer comprises a lower initial layer and wherein the lower initial layer comprises an organic material.

12. The method as recited in claim 8, wherein the initial via pattern layer comprises a top layer and wherein the one or more initial openings are multi-patterned.

13. The method as recited in claim 12, wherein the top layer comprises multiple via pattern openings created by memorizing two or more via lithographic mask steps into the top layer, wherein the material of the top layer is a low temperature oxide and/or nitride.

14. The method as recited in claim 8, wherein the integrated circuit structure further comprises:
a conductive layer overlaying and embedded in a base layer;
a protective layer overlaying the conductive layer and the base layer;
a dielectric layer overlaying the protective layer;
a sacrificial adhesive layer overlaying the dielectric layer; and
the hard mask layer overlaying the sacrificial adhesive layer.

15. An integrated circuit structure, comprising:
a coating layer located over a hard mask layer on the integrated circuit structure,
wherein the coating layer is a conformal deposition of an oxide, a boron nitride, or other nitride; and
an initial via pattern layer located over the coating layer,
wherein an initial via pattern layer has one or more initial openings located therein and
wherein the pattern of the one or more initial openings was etched into the coating layer and through openings in the hard mask layer.

16. The integrated circuit structure as recited in claim 15, wherein the hard mask layer comprises titanium nitride.

17. The integrated circuit structure as recited in claim 15, wherein the initial via pattern layer comprises:
a lower initial layer located over the coating layer and comprising an organic material; and
an upper initial layer located over the lower initial layer and comprising a Low Temperature Oxide (LTO) or a Silicon Anti-Reflective Coating (SiARC) material.

18. The integrated circuit structure as recited in claim 15, further comprising:
a conductive layer overlaying and embedded in a base layer;
a protective layer overlaying the conductive layer and the base layer;
a dielectric layer overlaying the protective layer; and
a sacrificial adhesive layer overlaying the dielectric layer,
wherein the hard mask layer overlays the sacrificial adhesive layer.

19. The integrated circuit structure as recited in claim 15, wherein the protective layer comprises a nitride, cyclique nitride or cobalt nitride material.

20. The integrated circuit structure as recited in claim 15, wherein the sacrificial adhesive layer comprises an oxide or Tetraethyl orthosilicate material.
